(19) United States
(12) Patent Application Publication
(10) Pub. No.: US 2006/0249077 A1
(43) Pub. Date: Nov. 9, 2006

(54) Multiple inlet atomic layer deposition reactor

(76) Inventors: DaeYoun Kim, Daedeog-gu (KR); Jeong Ho Lee, Yuseong-gu (KR); Yong Min Yoo, Yuseong-gu (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/429,533

(22) Filed: May 4, 2006

(30) Foreign Application Priority Data
May 9, 2005 (KR) 2005-0038606

(51) Int. Cl. C23C 16/00

(52) U.S. Cl. 118/723 MP

(57) ABSTRACT

A reactor configured to subject a substrate to alternately repeated surface reactions of vapor-phase reactants is disclosed. The reactor includes a reaction chamber, a plurality of inlets, and an exhaust outlet. The reaction chamber includes a reaction space. The reactor also includes a gas flow control guide structure within the reaction chamber. The gas flow control guide structure resides over the reaction space and is interposed between the plurality of inlets and the reaction space. The gas flow control guide structure includes a plurality of channels, and each of the channels extends from one of the inlets to an upstream periphery of the reaction space. Each of the channels progressively widens as the channel extends from the inlet to the reaction space. The reactor further includes a substrate holder in the reaction space.

### CROSS-REFERENCE TO RELATED APPLICATIONS

This application claims the benefit of Korean Patent Application No. 2005-0038606, filed on May 9, 2005, in the Korean Intellectual Property Office, the disclosure of which is incorporated herein by reference. This application is also related to U.S. Pat. No. 6,539,891, issued on Apr. 1, 2003, entitled CHEMICAL DEPOSITION REACTOR AND METHOD OF FORMING A THIN FILM USING THE SAME, the disclosure of which is incorporated herein by reference.

### BACKGROUND OF THE INVENTION

1. Field of the Invention

The present invention relates to an apparatus for growing thin films on a surface of a substrate. More particularly, the present invention relates to an apparatus for producing thin films on a surface of a substrate by subjecting the substrate to alternately repeated surface reactions of vapor-phase reactants.

2. Description of the Related Art

In manufacturing semiconductor devices, various methods and apparatuses have been developed to provide a high quality thin film on a substrate. Several methods have been used to form a thin film, employing surface reaction of a semiconductor substrate. The methods include vacuum evaporation deposition, Molecular Beam Epitaxy (MBE), different variants of Chemical Vapor Deposition (CVD) (including low-pressure and organometallic CVD and plasma-enhanced CVD), and Atomic Layer Epitaxy (ALE). ALE was studied extensively for semiconductor deposition and electroluminescent display applications, and has been more recently referred to as Atomic Layer Deposition (ALD) for the deposition of a variety of materials.

ALD is a method of depositing thin films on a surface of a substrate through a sequential introduction of various precursor species to the substrate. The growth mechanism tends to rely on the adsorption of a first precursor on the active sites of the substrate. Conditions are such that no more than a monolayer forms, thereby self-terminating the process. Exposing the substrate to the first precursor is usually followed by a purging stage or other removal process (e.g., a “pump down”) wherein any excess amounts of the first precursor as well as any reaction by-products are removed from the reaction chamber. The second precursor is then introduced into the reaction chamber at which time it reacts with the first precursor and this reaction creates the desired thin film. The reaction terminates once all of the available first precursor species adsorbed on the substrate has been reacted. A second purge or other removal stage is then performed which rids the reaction chamber of any remaining second precursor or possible reaction by-products. This cycle can be repeated to grow the film to a desired thickness. The cycles can also be more complex. For example, the cycles may include three or more reactant pulses separated by purge or other removal steps.

A conventional reactor designed for CVD is not suitable for efficient ALD because such a reactor is designed to simultaneously introduce reactants into its reaction chamber. In addition, in a reactor in which a reactant is introduced downward over a semiconductor substrate, a showerhead is typically used between a reactant inlet and the substrate to provide an evenly distributed flow over the substrate. Such a configuration, however, complicates the reactant flow and requires a large size reactor, making rapid switching of reactant gases difficult. Accordingly, there is a need to provide a reactor suitable for ALD, which allows prompt switching of one reactant to another while forming a high quality thin film.

### SUMMARY OF THE INVENTION

One aspect of the invention provides an atomic layer deposition reactor. The reactor comprises: a reaction chamber comprising a reaction space; a plurality of inlets; an exhaust outlet; and a gas flow control guide structure. The gas flow control guide structure resides over the reaction space. The gas flow control guide structure is interposed between the plurality of inlets and the reaction space. The gas flow control guide structure comprises a plurality of channels. Each of the plurality of channels extends from a respective one of the plurality of inlets to a first portion of a periphery of the reaction space. Each of the plurality of channels widens as the channel extends from the inlet to the reaction space. The reactor also includes a substrate holder positioned to expose a supported substrate to the reaction space.

Another aspect of the invention provides an atomic layer deposition (ALD) reactor. The reactor comprises: a reactor cover comprising a plurality of inlets and an exhaust outlet. The reactor also includes a reactor base comprising a substrate holder. The reactor base and the reactor cover are configured to define a reaction chamber. The reaction chamber comprises a reaction space. The reaction space comprises an upstream periphery and a downstream periphery positioned on the opposite side from the upstream periphery. The reactor further comprises a plurality of gas flow control plates positioned within the reactor chamber. The plurality of gas flow control plates reside over the reaction space. The plurality of gas flow control plates are stacked over one another. Each of the plurality of gas flow control plates at least partially defines an inflow channel configured to guide a reactant supplied through one of the plurality of the inlets to the upstream periphery of the reaction space.

Yet another aspect of the invention provides a method of depositing a reactant on a substrate in a reaction space. The reaction space comprises an upstream periphery and a downstream periphery. The method comprises a plurality of atomic layer deposition cycles, and each comprises: supplying a first reactant to the reaction space; reacting the first reactant with a surface of the substrate; removing excess first reactant from the reaction space; supplying a second reactant to the reaction space; reacting the second reactant with the surface of the substrate; and removing excess second reactant from the reaction space. Supplying the first reactant comprises in sequence: flowing the first reactant outwardly and horizontally at a first vertical level toward the upstream periphery of the reaction space while widening a first flow path of the first reactant, and flowing the first reactant vertically to the upstream periphery and into the reaction space. Supplying the second reactant comprises in sequence: flowing the second reactant horizontally at a second vertical level toward the upstream periphery of the reaction space while widening a second flow path of the second reactant, and flowing the second reactant vertically from the second vertical level to the upstream periphery and into the reaction space.

Yet another aspect of the invention provides a method of assembling an atomic layer deposition (ALD) reactor. In the method, a reactor cover is provided comprising a top plate and a sidewall. The top plate comprises a plurality of inlets, and defines an upper surface of a reaction chamber. The sidewall defines a side surface of the reaction chamber. The reaction chamber comprises a reaction space. Then, a gas flow control guide structure is placed into the reaction chamber so that at least a portion of the gas flow control guide structure is in contact with the upper surface of the reaction chamber. The gas flow control guide structure comprises a plurality of inflow channels. Each of the plurality of inflow channels extends from a respective one of the plurality of inlets to a first portion of a periphery of the reaction space. Next, a reactor base is provided to be in sealing contact with the sidewall of the reactor cover so that an upper surface of the reactor base and a lower surface of the gas flow control guide structure define the reaction space.

### BRIEF DESCRIPTION OF THE DRAWINGS

FIG. 1 is a schematic cross-sectional view of a prior art reactor including a single gas flow control plate.

FIG. 2 is a schematic cross-sectional view of a reactor including a plurality of reactant inlets and a plurality of gas flow control plates in accordance with one embodiment.

FIGS. 3A and 3B are schematic perspective views of the gas flow control plates of FIG. 2.

FIG. 4 is a schematic perspective view of the reactor of FIG. 2.

FIG. 5 is a flowchart of a method of forming a thin film, using the reactor of FIG. 2 in accordance with one embodiment.

FIG. 6 is a schematic cross-sectional view of a reactor having a protective grounding plate in accordance with another embodiment.

FIG. 7 is a schematic cross-sectional view of a reactor including a purging gas channel in accordance with yet another embodiment.

### DETAILED DESCRIPTION OF THE PREFERRED EMBODIMENT

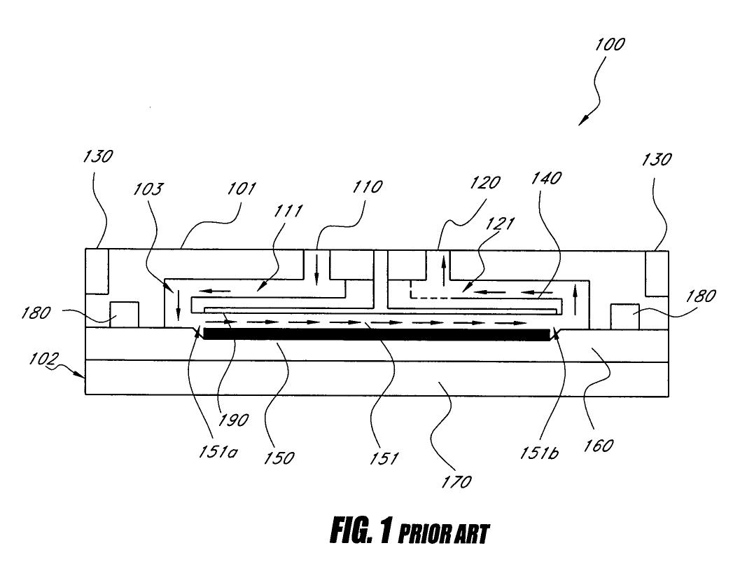

FIG. 1 illustrates an ALD reactor suitable for a sequential introduction of reactants into a reaction space, similar to that disclosed in U.S. Pat. No. 6,539,891. In FIG. 1, a reactor 100 includes a reactor cover 101, a reactor base 102, and a gas flow control plate 140.

The reactor cover 101 constitutes an upper part of the reactor 100, and has a short cylinder-like structure with its top blocked. The reactor cover 101 includes a reactant inlet 110 and an exhaust outlet 120. A portion of a side wall of the reactor cover 101 is surrounded by a cover heater 130.

The reactor base 102 is positioned below the reactor cover 101. The reactor base 102 can move vertically with respect to the reactor cover 101. A substrate 150 can be loaded or unloaded while the reactor base 102 is separated from the reactor cover 101. For deposition, the reactor base 102 moves up and is in sealing contact with the reactor cover 101. The reactor base 102 is configured to define a reaction chamber 103 with the reactor cover 101. The reactor base 102 includes a substrate holder 160 and a substrate heater 170. The substrate 150 on which a thin film will be formed is mounted on the substrate holder 160.

The gas flow control plate 140 is housed in the reaction chamber 103 and attached to the reactor cover 101. A lower surface of the gas flow control plate 140 and an upper surface of the substrate holder 160 define a reaction space 151 in which the substrate 150 will be processed. A portion of a top surface of the gas flow control plate 140 and a portion of an inner lower surface of the reactor cover 101 define an inflow channel or passage 111, which provides fluid communication between the inlet 110 and an upstream periphery 151a of the reaction space 151. Another portion of the top surface of the gas flow control plate 140 and another portion of the inner lower surface of the reactor cover 101 define an outflow channel or passage 121, which provides fluid communication between the exhaust outlet 120 and a downstream periphery 151b of the reaction space 151. The downstream periphery 151b of the reaction space 151 is on the opposite side from the upstream periphery 151a, as shown in FIG. 1. The gas flow control plate 140 is configured to guide a gas flow traveling from the inlet 110 through the inflow channel 111, the reaction space 151, and the outflow channel 121 to the exhaust outlet 120.

The ALD reactor 100 of FIG. 1 is configured to minimize its reaction space 151 so as to allow rapid switching of one reactant to another. In addition, the reactor uses a gas flow control plate that evenly distributes a reactant before it reaches the substrate in the reaction space. This structure generates a flattened horizontal flow of the reactant over a substrate. Such a configuration provides a fast reactant flow over the substrate while permitting surface reaction with the substrate. Thus, reactant and purging gas supplying time can be minimized. Accordingly, overall processing time for forming thin films can be significantly reduced.

Introducing different reactants through separate channels to the reaction space further facilitates switching of one reactant to another in the reaction space while minimizing chance that the reactants might meet in the gas phase. Preferred embodiments of the invention are described below with reference to the accompanying drawings. In the drawings, like reference numerals indicate identical or functionally similar elements.

In one embodiment, an ALD reactor includes a reaction chamber, a plurality of inlets, an exhaust outlet, a gas flow control guide structure, a substrate holder, and an outer wall. The reaction chamber includes a reaction space in which a substrate will be processed. The plurality of inlets are configured to separately supply reactants from external reactant sources to the reaction space. The gas flow control guide structure is preferably interposed between the plurality of inlets and the reaction space. The gas flow control guide structure includes a plurality of inflow channels or passages, each of which extends from one of the plurality of inlets to an upstream periphery of the reaction space. Preferably, each of the plurality of inflow channels is defined in part by a different gas flow control plate, and progressively widens as the channel extends from the inlet to the reaction space.

Each of the plurality of the inflow channels is configured to evenly spread a reactant in a fanned and flattened shape with its end (curved in the illustrated embodiment) being in direct fluid communication with the upstream periphery of the reaction space. This configuration allows the reactant to be uniformly distributed over the substrate.

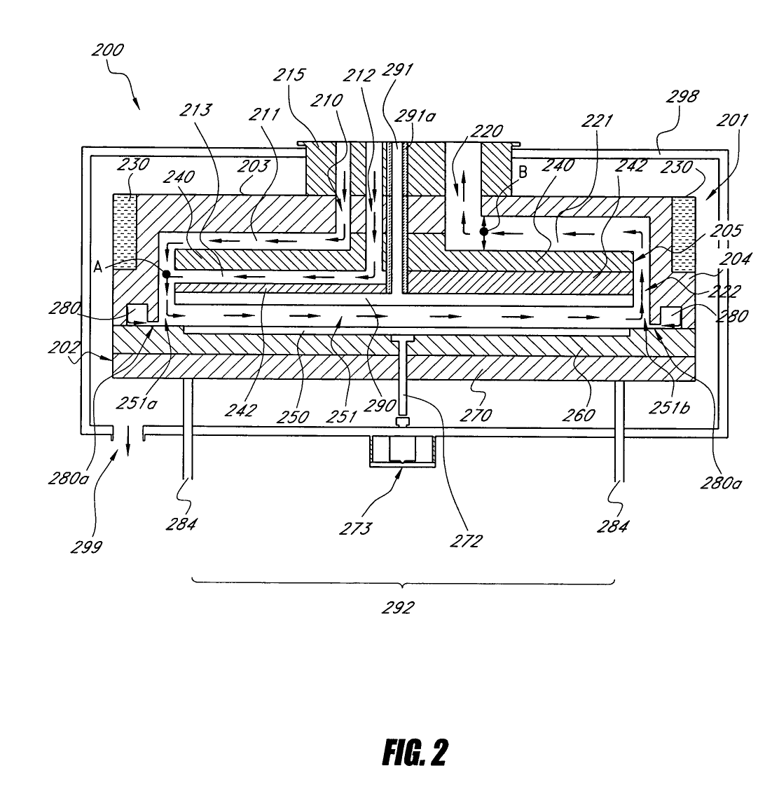

FIG. 2 illustrates an ALD reactor 200 according to one embodiment. The ALD reactor 200 includes a reactor cover 201, a reactor base 202, a reactor base driver 292, a gas flow control guide structure 205, a plasma-generating electrode 290, and an outer wall 298. The reactor cover 201 and the reactor base 202 are in reversible sealing contact with each other and define a reaction chamber. The reaction chamber includes a reaction space 251 in which a substrate 250 is processed. The reaction space 251 is defined between an upper surface of the reactor base 202 and a lower surface of the gas flow control guide structure 205. The reaction space 251 includes an upstream periphery 251a into which a reactant is introduced and a downstream periphery 251b from which excess reactant and reaction by-products are exhausted. The reactor base 202 is detachable from the reactor cover 201 for loading or unloading a substrate 250, as described in more detail below. The outer wall 298 is configured to pressure-tightly house the reactor cover 201 and the reactor base 202, and can be evacuated through an outer exhaust 299 connected to a vacuum pump.

The reactor cover 201 has a top plate 203 of a generally circular plate-like shape and a sidewall 204 extending downward from a periphery of the top plate 203. In the illustrated embodiment, the top plate 203 and the sidewall 204 are integrally formed such that the reactor cover 201 generally has a short cylinder-like shape with one of the ends blocked by the top plate 203. The reactor cover 201 includes first and second inlets 210 and 212, an exhaust outlet 220, and a gas manifold 215. The reactor cover 201 is preferably formed of a metal. In certain embodiments, the reactor cover 201 may be formed of a ceramic material.

The first and second inlets 210 and 212 preferably extend through the top plate 203, preferably a central portion of the top plate 203. The inlets 210 and 212 are in fluid communication with reactant sources (not shown). The first and second inlets 210 and 212 are configured to supply a first reactant X and a second reactant Y, respectively. Preferably, the reactants X and Y are introduced in vapor phase through the inlets 210 and 212. An exemplary material of the reactant X is trimethylaluminum (TMA), and an exemplary material for the reactant Y is H₂O, and vice versa. TMA and O₂ may be used as reactants X and Y, respectively, for plasma-enhanced ALD (PEALD). In PEALD mode, radio frequency (RF) power pulse is applied to the plasma-generating electrode 290 to generate plasma in the reaction space 251 while O₂ is supplied into the reaction space 251. Similarly, other metal volatile species can be used to deposit metal oxide films. Gas supply and plasma pulse sequence of PEALD are described in U.S. Pat. No. 6,645,574 and U.S. Patent Application Publications 2004/0009307 and 2005/0037154, the disclosures of which are incorporated herein by reference. In addition, the inlets 210 and 212 are in fluid communication with an inert gas source (not shown), and are used to supply an inert gas into the reaction space 251. Examples of the inert gas include helium, argon, xenon, nitrogen, etc. Depending on reactants and conditions, “inert” gases can include gases that are reactive under higher temperature or under plasma power, such as N₂, O₂, etc. Valves may be located upstream of the inlets 210 and 212 to control the flows of the reactants and the inert gas. For example, 3-way valves can be used to switch gas supply between the inert gas and the reactants for each of the inlets 210 and 212. In addition, the ALD reactor 200 preferably includes a switching mechanism for controlling the valves. In one embodiment, a computer is used to alternate supplies of the reactants and the inert gas.

The reactor cover 201 also includes the exhaust outlet 220 extending through the top plate 203. In the illustrated embodiment, the exhaust outlet 220 is positioned at the central portion of the top plate 203 adjacent the inlets 210 and 212. In other embodiments, the exhaust outlet may be positioned at a periphery of the top plate 203 or on the sidewall 204 of the reactor cover 201.

In addition, the reactor cover 201 includes the gas manifold 215, which in the illustrated embodiment is a flanged cylinder-type gas manifold formed over a central portion of the top plate 203. The gas manifold 215 includes vertical through-holes which are in fluid communication with the inlets 210 and 212 and the exhaust outlet 220. The gas manifold 215 extends upward to the outside of the outer wall 298.

The reactor cover 201 also includes the cover heater 230 on outer surfaces of the reactor cover 201. The cover heater 230 is configured to resistively heat the reactor cover 201 to a predetermined temperature so as to prevent a reactant from condensing on an inner surface of the reaction cover 201. In order to prevent loss of heat to the outer wall 298, the reactor cover 201 has a minimum heat conduction path to the outer wall 298, i.e., it is fixed to the outer wall 298 through the flanged cylinder-type gas manifold 215. Due to this structure, even though the inner temperature of the reaction chamber is, for example, about 300° C., the temperature of the outer wall 298 can be maintained at about 65° C. or below. Additional heaters (not shown) may be attached to the gas manifold 215 or inserted into the gas manifold 215. In other arrangements, the cover heater can be located elsewhere, or the chamber can be configured to absorb remotely generated energy, e.g., inductive heat, radiant heat, microwave energy, etc.

In addition, the reactor cover 201 includes an encircling inert gas supply groove 280 on a lower surface of the sidewall 204 where the reactor cover 201 contacts the reactor base 202. The groove 280 is preferably formed along the entire contact surface between the reactor cover 201 and the reactor base 202. The groove 280 is in fluid communication with an inert gas source (not shown). An inner rim of the sidewall 204 is configured to be spaced apart from the reactor base 202 with a small gap (e.g., about 0.5 mm) 280a, which is ring-shaped along the groove. The groove 280 is allowed to have a gas pressure higher than the process pressure of the reaction chamber so that the inert gas can uniformly flow into the reaction chamber through the small gap 280a. The illustrate reactor cover 201 has the inert gas supply groove 280 configured to supply the inert gas. The inert gas continuously flows through the small gap 280a during the deposition process in order to prevent a thin film from being formed at the contact area, i.e., an outer rim of the sidewall 204 where a sealing mechanical contact is formed, while allowing repeated separation of the base 202 from the cover 201 for loading and unloading substrates 250 in sequence. Films deposited at the contact area may peel off during repetitive contact and detachment for opening and closing the chamber, which may generate contaminant particles in the inner portion of the reaction chamber.

Although not shown, the reactor cover 201 may further include a protrusion covering the periphery of a substrate 250. The protrusion blocks reactants from contacting the periphery of the substrate, thereby preventing a film formation on the periphery.

The reactor base 202 includes a substrate holder 260 and a substrate heater 270. The substrate holder 260 is configured to support a substrate 250, and preferably has a recess to secure the substrate 250 and expose only a top surface of the substrate 250. The substrate heater 270 is integrally attached to a lower surface of the substrate holder 260, and is configured to heat the substrate 250 to a predetermined temperature during a deposition process. The substrate holder 260 is formed of a metal, and is preferably electrically grounded. A skilled artisan will appreciate that the structure and material of the reactor base 202 can be varied, depending on the design of a reactor.

The reactor base driver 292 is configured to move the reactor base 202 in a vertical direction. The driver 292 includes a central supporting pin 272, and a vertically moving mechanism 284. The central supporting pin 272 is positioned in a central portion of the substrate holder 260, and extends downwards below the substrate heater 270, as shown in FIG. 2. Preferably, the vertically moving mechanism 284 includes three rod-shaped connectors connected to a bottom surface of the substrate heater 270. In FIG. 2, one of the three connectors is hidden from the view. The vertically moving mechanism 284 is configured to provide the reactor base 202 with a vertical movement, using a driving device (not shown) such as a motor.

Before or after a deposition process, the reactor base 202 is moved down, and is detached from the reactor cover 201 so that the reaction chamber is open. While the reaction chamber is open, the central supporting pin 272 interacts with a pin engagement mechanism 273 to either separate the substrate 250 from the holder 260 or mount the substrate 250 on the holder 260. The substrate 250 can be loaded or unloaded by robotics through a gate valve (not shown) in the outer wall 298 while the central supporting pin 272 is lifted up relative to the substrate holder 260.

After placing a substrate for deposition, the central supporting pin 272 is moved down so that the substrate 250 is mounted on the substrate holder 260. Then, the reactor base 202 is lifted up by the moving mechanism 284 close to the reactor cover 201 so that the reaction chamber is closed.

The gas flow control guide structure 205 includes an upper gas flow control plate 240 and a lower gas flow control plate 242. The upper gas flow control plate 240 is stacked over the lower gas flow control plate 242. A central portion of the upper gas flow control plate 240 is attached to an inner bottom surface of the reactor cover 201. In other embodiments, the gas flow control guide structure 205 may further include additional gas control plates, depending on the number of reactants supplied into the reactor. The gas flow control plates 240 and 242 can be assembled into and detached from the reactor cover 201. This configuration allows easy maintenance and cleaning. In certain embodiments, however, the gas flow control guide structure may be integrally formed with the reactor cover 201 rather than having detachable gas flow control plates described above. The gas flow control guide structure 205 defines a first inflow channel 211, a second inflow channel 213, and an outflow channel 221, which will be described below in detail.

The plasma-generating electrode 290 is configured to generate plasma in the reaction space 251 during a deposition process. The plasma-generating electrode 290 may also or alternatively generate plasma for cleaning the reaction chamber. The illustrated plasma-generating electrode 290 faces the substrate holder 260 and is preferably part of the lower gas flow control plate 242. In another embodiment, the plasma-generating electrode is in the form of a plate attached to the lower surface of the lower gas flow control plate 242. The plasma-generating electrode 290 is formed of a conductive material, such as stainless steel, aluminum, copper, nickel, titanium, or their alloys. The plasma-generating electrode 290 is electrically connected to an external RF power source (not shown). The illustrated electrode 290 is electrically connected to a conductive line 291 which extends upward to the outside of the reactor 200. The conductive line 291 is surrounded by an insulator 291a so as to electrically insulate the conductive line 291 from the upper and lower gas flow control plates 240 and 242 and the reactor cover 201, to the extent these are conductive. The plasma-generating electrode 290 may be omitted if plasma is not used.

The outer wall 298 is configured to pressure-tightly enclose the reactor cover 201 and the reactor base 202. The outer wall 298 includes a top opening for the flanged cylinder-type gas manifold 215; bottom openings for the vertically moving mechanism 284; the outer exhaust 299 for pumping down the outer chamber and minimizing particles from cross-contamination of the multiple reactants; and a gate valve (not shown) for loading and unloading wafers.

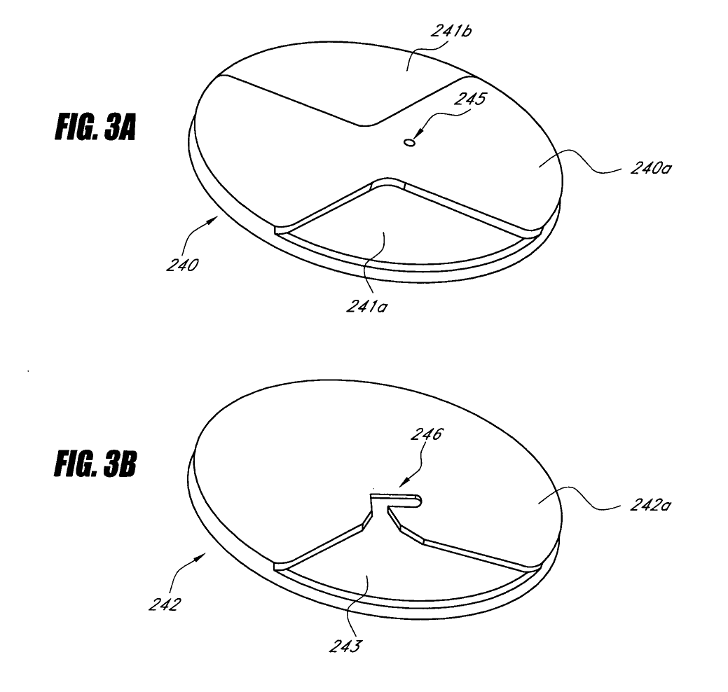

Referring to FIG. 3A, the upper gas flow control plate 240 has first and second grooves 241a and 241b tapered toward its central portion. In other words, the grooves 241a and 241b widen toward edge portions of the upper gas flow control plate 240 as they extend from the central portion to the edge portions. The illustrated grooves 241a and 241b are in a form of a sector of a circle. The first groove 241a defines a first inflow channel or passage 211 (FIG. 2) with a portion of an inner bottom surface of the reactor cover 201 for the reactant X supplied through the first inlet 210, as shown in FIG. 2. The second groove 241b defines an outflow channel or passage 221 (FIG. 2) with another portion of the inner bottom surface of the reactor cover 201 for excess reactant and reaction by-products, as shown in FIG. 2. The upper gas flow control plate 240 also has a through-hole 245 vertically penetrating the upper gas flow control plate 240. The through-hole 245 is configured to be in fluid communication with the second inlet 212 (FIG. 2) and a groove 246 (FIG. 3B) of the lower gas flow control plate 242 which will be described below. The upper gas flow control plate 240 may be formed of a metallic or ceramic material.

In certain embodiments where multiple gas flow control plates are employed, each of the gas flow control plates, except for a lowermost plate, has at least one vertical through-hole as described above. In one embodiment where n number of plates are stacked over one another, an n-th plate from the bottom has n-1 through-holes. For example, where there are three stacked plates, a top plate (a 3rd plate from the bottom) has two through-holes, and a middle plate (a 2nd plate from the bottom) has one through-hole and one groove similar to the groove 246 (FIG. 3B). In addition, a bottom plate has no through-holes and one groove similar to the groove 246 (FIG. 3B). In a plate having multiple through-holes, the through-holes are positioned at horizontally different locations so that the inflow channels separately fluid-communicate with the inlets. In addition, the through-holes of the stacked plates are vertically aligned to allow fluid communication between the inflow channels and the inlets.

The upper gas flow control plate 240 also includes a solid part 240a between or around the grooves 241a and 241b. The solid part 240a forms sidewalls of the grooves 241a and 241b, and is configured to force the flow outward from the first inlet, around a plate periphery, through the reaction space, around another plate periphery, and inward to the exhaust outlet.

Referring to FIG. 3B, the lower gas flow control plate 242 has a groove 243 tapered toward its central portion. The groove 243 is in a form of a sector of a circle. The groove defines a second inflow channel 213 (FIG. 2) with a lower surface of the upper gas flow control plate 240 for the reactant Y supplied through the second inlet 212, as shown in FIG. 2. Referring back to FIG. 3B, the groove 243 further extends to a central groove 246 of the lower gas flow control plate 242 so that the second inflow channel 213 is in fluid communication with the second inlet 212 via the through-hole 245 of the upper gas flow control plate 240. In addition, a lower surface of the lower gas flow control plate 242 and an upper surface of the substrate holder 260 define the reaction space 251 in which the substrate 250 will be processed. A gap between the lower gas flow control plate 242 and the substrate holder 260 may be adjusted to provide an optimal volume and electrode spacing for the reaction space 251. In one embodiment, the gap between the lower gas flow control plate 242 and the substrate holder 260 is between about 1 mm and about 10 mm. Preferably, the lower gas flow control plate 242 is formed of an insulating, e.g., ceramic material. A skilled artisan will appreciate that the shapes and structures of the grooves of the gas flow control plates 240 and 242 may be varied, depending on the design of a reactor.

The lower gas flow control plate 242 also includes a solid part 242a around the grooves 243 and 246. The solid part 242a forms sidewalls of the grooves 243 and 246, forcing the flow outward from the second inlet, around a plate periphery, through the reaction space, around another plate periphery, and inward to the exhaust outlet defined by the upper gas flow control plate 240.

Referring to FIGS. 2 and 3A, the outflow channel 221 defined by the second groove 241b of the upper gas flow control plate 240 narrows as it extends inwardly toward the exhaust outlet 220. Thus, reactant gases may react with each other or be deposited on walls in a bottleneck region B near the exhaust outlet 220 if the gas flow is restricted in the region B. In one embodiment, a cross-sectional area of the exhaust outlet 220 is equal to or greater than a total cross-sectional area of the first and second inlets 210 and 212. In addition, a cross-sectional area of the outflow channel 221 is preferably configured to be equal to or greater than a cross-sectional area of either of the inflow channels 211, 213, and more preferably greater than a total cross-sectional area of the first and second inflow channels 211 and 213. As best seen from FIG. 2, the top plate 203 of the reactor cover 201 is thinner on the exhaust side compared to the inlet side, creating a high-ceilinged outflow channel 221. These configurations alleviate stagnation of the exhaust gases in the bottleneck region B and thus minimize the undesired reaction or deposition.

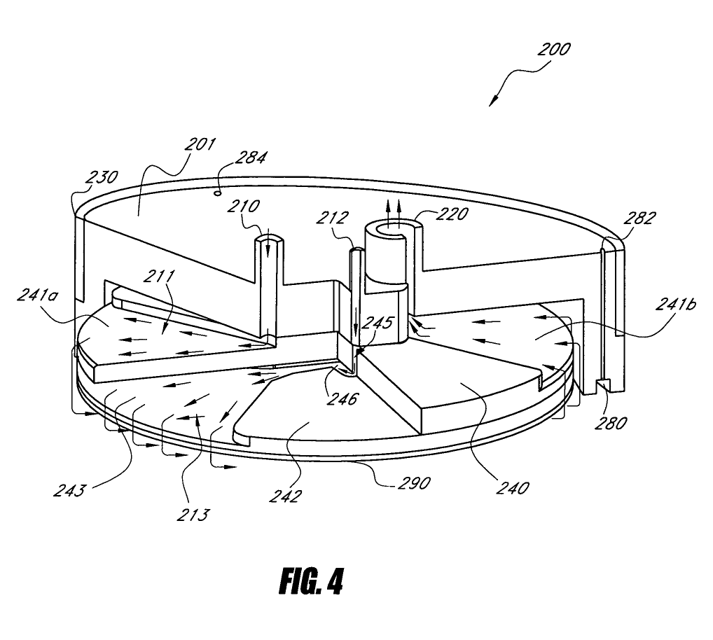

FIG. 4 illustrates flows of reactants and exhaust gases within the reactor 200 during its operation. At a deposition step, the reactant X is supplied through the first inlet 210 while an inert gas is supplied through the second inlet 212. The reactant X passes through the first inflow channel 211, while being spread into a fanned and flattened flow shape. The reactant X then turns downward at the edge of the upper gas flow control plate 240 toward the upstream periphery of the reaction space. The inert gas flows out from the second inflow channel 213 in a manner similar to that of the reactant X. The inert gas prevents the reactant X from entering the second inflow channel 213. The flow of the reactant X continues toward the reaction space and arrives at the upstream periphery of the reaction space. As shown in FIG. 4, because the grooves 241a and 213 for the reactant X and the inert gas have wide mouths in fluid communication with the reaction space underneath these plates, the reactant X and the inert gas are widely spread when entering the reaction space. This configuration facilitates uniform deposition of the reactant on the substrate 250.

Then, as shown in FIG. 2, the reactant X flows over the substrate 250 in a horizontal direction from the upstream periphery 251a toward the downstream periphery 251b through the reaction space 251. At the downstream periphery 251b, exhaust gases such as excess reactant X, the inert gas, and any reaction by-products, flow upward through a vertical exhaust passage 222 toward the exhaust outlet 220. The exhaust gases flow through the outflow channel 221 and exit through the exhaust outlet 220. As shown, the exhaust outlet 220 has a considerably larger width or diameter than either of the inlets 210, 212, and preferably larger than the sum of their cross-sectional areas.

Referring back to FIG. 4, in a subsequent pulse, the reactant Y is supplied through the second inlet 212 while an inert gas is supplied through the first inlet 210. The reactant Y travels through the vertical through-hole 245 of the upper gas flow control plate 240 and the central groove 246 of the lower gas flow control plate 242 to the second inflow channel 213. Then, the reactant Y continues to flow toward and through the reaction space 251 (FIG. 2) in a manner similar to that of the reactant X described above. The inert gas flowing out from the first inlet channel 211 prevents the reactant Y from entering the first inflow channel 211.

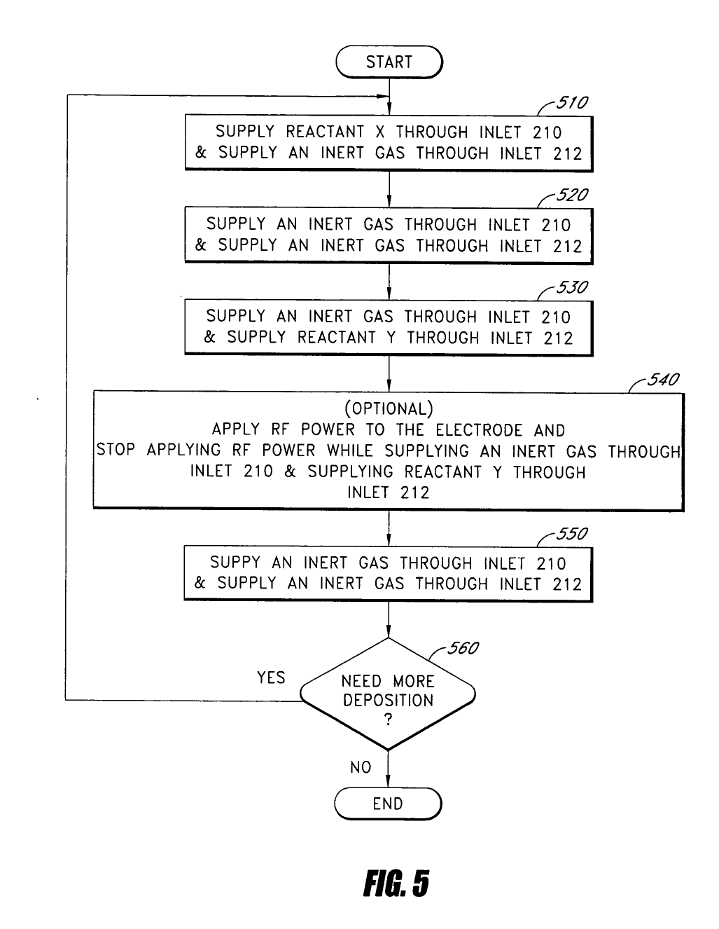

Referring to FIGS. 2 and 5, an exemplary ALD method of depositing a thin film using the reactor 200 is described. The illustrated method employs two reactants. However, in other embodiments where more than two reactants are used, the method will include additional steps for each of the additional reactants. In that event, preferably additional gas flow control plates, similar to the lower gas flow control plate 242, are provided for each additional reactant in the ALD recipe.

In step 510 of FIG. 5, the reactant X is supplied through the first inlet 210 while an inert gas is supplied through the second inlet 212. The reactant X is guided by the first inflow channel 211 into the reaction space 251 while being prevented from entering the second inflow channel 213 by the inert gas. This causes the reactant X to be adsorbed onto a substrate 250 positioned in the reaction space 251. The step 510 is preferably conducted for a sufficient period of time to saturate the substrate surface with reactant X. Desirably, the adsorption is self-limiting to no more than a molecular monolayer. Next, in step 520, excess reactant X and any reaction by-products are purged (or otherwise removed). The preferred purging step is conducted by supplying a purging or inert gas through both of the first and second inlets 210 and 212.

Subsequently, in step 530, the reactant Y is supplied through the second inlet 212 while an inert gas is supplied through the first inlet 210. The reactant Y is guided by the second inflow channel 213 into the reaction space 251 while being prevented from entering the first inflow channel 211 by the inert gas flowing out from the first inflow channel 211. This causes the reactant Y to react with adsorbed species or fragments of reactant X on the substrate 250. Optionally, plasma may be generated directly over the substrate 250 while reactant Y is supplied by activating the electrode 290, as shown in step 540. The step 540 is conducted for a sufficient period of time so that the adsorbed monolayer is completely reacted. When plasma is not used and the step 540 is omitted, the step 530 is conducted for a sufficient period of time so that the adsorbed monolayer is completely reacted.

Next, in step 550, excess reactant Y and any reaction by-products are purged. This purging step 550 is conducted by supplying a purging or inert gas through both of the first and second inlets 210 and 212. Then, in step 560, if additional deposition is required, the steps 510 through 550 are repeated in a plurality of cycles. Preferably, the steps 510-550 are sequentially repeated at least 5 times. Otherwise, the deposition is completed. During the steps described above, the valves located upstream of the inlets 210 and 212 are used to control supplies of the reactants and inert gas.

In another embodiment, reactant Y may be supplied continuously if reactants X and Y do not thermally react with each other. For example, O₂ gas or its mixture with an inert gas is supplied continuously through the second inlet 212 while TMA supply is pulsed through the first inlet 210. In this embodiment, the step 530 may be omitted and the steps 510, 520, 540, and 550 are repeated. In the step 510, TMA is supplied through the first inlet 210. In the step 520, an inert gas is supplied through the first inlet 210. In the step 540, plasma is generated in the reaction space. In the step 550, an inert gas is supplied through the first inlet 210. The duration of step 550 can be very short or even may be omitted because the chemically active species generated by plasma disappear quickly after the plasma is turned off.

In another embodiment, an ALD method may start with a non-adsorbing reactant. In certain embodiments, additional reactants may be used for film formation. For example, the substrate surface may be treated with an initial surface treatment agent, e.g., water or other hydroxyl-forming agent, prior to supplying the reactant X into the reaction space. A reducing species may also be used in each cycle to strip ligands, which help make the process self-limiting, from adsorbed species. In addition, additional reactants that contribute to film may be used in each cycle or every few cycles.

In order to conduct the process explained above, the ALD reactor 200 preferably includes a control system. The control system controls the supplies of the reactants and inert gas to provide desired alternating and/or sequential pulses of reactants. The control system can comprise a processor, a memory, and a software program configured to conduct the process. It may also include other components known in the industry. Alternatively, a general purpose computer can be used for the control system. The control system automatically opens or closes valves on the reactant and inert gas lines according to the program stored in the memory.

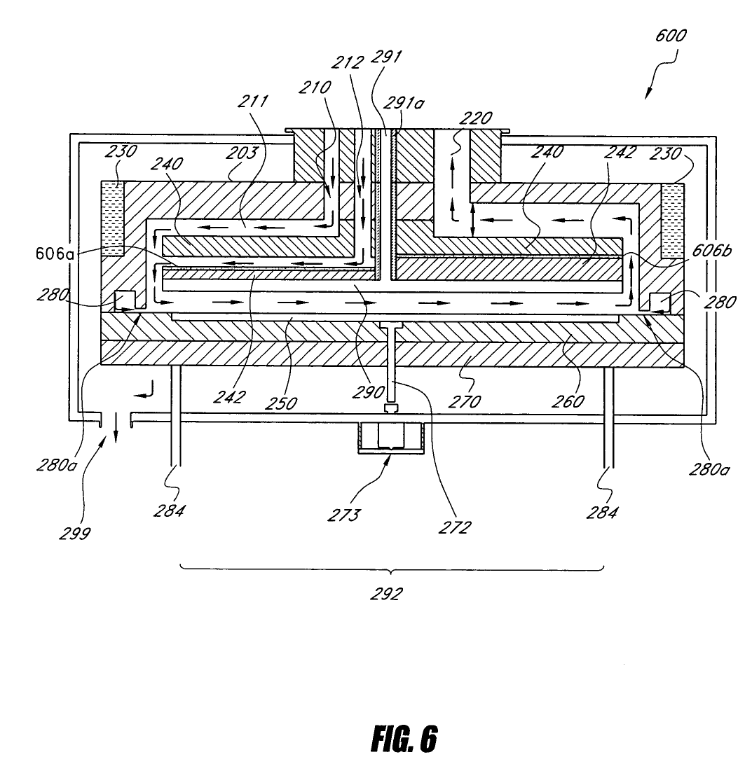

FIG. 6 illustrates another embodiment of an ALD reactor 600. In FIG. 6, like reference numerals indicate similar components to those shown in FIG. 2. Descriptions of similar components are omitted. In the illustrated embodiment, preferably, the lower gas flow control plate 242 is formed of an insulating (e.g., ceramic) material whereas the upper gas flow control plate 240 and the reactor cover 201 are formed of a metal or a metal alloy. The upper gas flow control plate 240 and the reactor cover 201 are preferably grounded.

The reactor 600 further includes a protective grounding plate 606 which is also grounded. The protective grounding plate 606 serves to prevent parasitic plasma which otherwise tends to occur near the inlets 210 and 212 and the exhaust outlet 220 when the reactor 600 is used for PEALD.

A first portion 606a of the protective grounding plate 606 is positioned on a bottom surface of the groove of the lower gas flow control plate 242 at the inlet side. A second portion 606b of the protective grounding plate 606 is interposed between the upper and lower gas flow control plates 240 and 242 at the exhaust side. The protective grounding plate 606 is preferably formed of a metal (e.g., copper, aluminum, nickel, titanium, stainless steel) or a metal alloy. The grounding plate 606 may be in the form of a plate which can be laminated or otherwise assembled onto the gas flow control plates 240 and 242. In certain embodiments, a protective grounding film may be formed in place of the grounding plate 606. The grounding film may be formed by coating a metallic material onto the upper surface of the lower gas flow control plate 242. In one embodiment where the upper gas flow control plate 240 is formed of a metal and is grounded, the protective grounding plate 606 can be grounded by simply being in contact with the upper gas flow control plate 240. Thus, no additional electrical connection is required for grounding the protective grounding plate or film at the exhaust side.

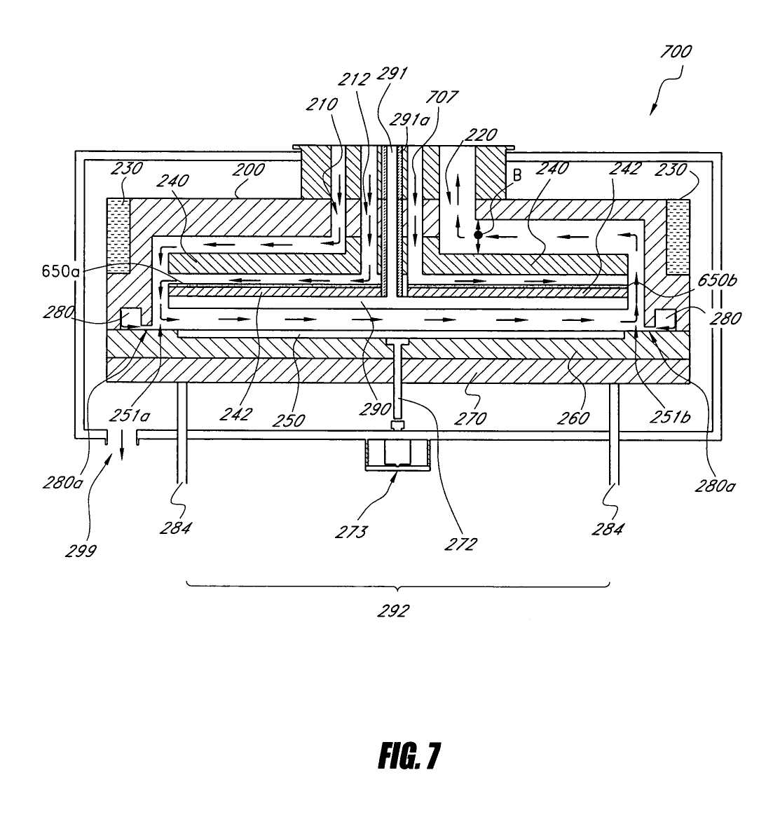

FIG. 7 illustrates another embodiment of an ALD reactor 700. In FIG. 7, like reference numerals indicate similar components to those shown in FIG. 2. Descriptions of similar components will be omitted.

The reactor 700 further includes a purging gas channel 707 configured to supply a purging inert gas to the downstream periphery 251b of the reaction space 251. The purging gas is directly introduced to the downstream periphery 251b without passing over the substrate 250. The purging gas dilutes excess reactants and any reaction by-products flowing out from the reaction space 251. The purging gas inhibits the reactants and the by-products from reacting with each other or condensing at or near the exhaust outlet 220, thereby reducing undesired deposition or generation of impurities.

The reactor 700 may also include a protective grounding plate or film 650 which is electrically grounded. The protective grounding plate 650 serves to prevent parasitic plasma which otherwise tends to occur near the inlets 210 and 212 and the exhaust outlet 220 when the reactor 700 is used for PEALD.

A first portion 650a of the protective grounding plate 650 is positioned at the inlet side on a bottom surface of a groove of the lower gas flow control plate 242. A second portion 650b of the protective grounding plate 650 is positioned at the outlet side on a bottom surface of the purging gas channel 707 which is a portion of an upper surface of the lower gas flow control plate 242. The configuration and material of the protective grounding plate 650 are similar to those of the protective grounding plate 606 of FIG. 6, and thus further details are omitted.

In the embodiments described above, only two reactants are used for an ALD process, and the examples of O₂ plasma pulses separated from TMA pulses is given. In certain embodiments, however, three or more reactants may be used for an ALD process. The three or more reactants may be supplied sequentially and cyclically into the reaction space, separated in time and space, using valves and plates as described above. Preferably, during any given reactant pulse through one inlet, purge gas is provided through all other inlets. Preferably, all inlets are purged between reactant pulses. Plasma can optionally be employed during one or more of the reactant pulses. In an embodiment, some of the reactants may be simultaneously supplied, depending on the recipe in accordance with various variances on truly separated ALD reactions. In addition, a skilled artisan will appreciate that the reactors of the embodiments described above can be adapted to various other types of vapor deposition processes.

Although various preferred embodiments and the best mode have been described in detail above, those skilled in the art will readily appreciate that many modifications of the exemplary embodiment are possible without materially departing from the novel teachings and advantages of this invention.

We claim:

1. An atomic layer deposition (ALD) reactor, comprising:
a reaction chamber comprising a reaction space;
a plurality of inlets;
an exhaust outlet;
a gas flow control guide structure residing over the reaction space, the gas flow control guide structure being interposed between the plurality of inlets and the reaction space, the gas flow control guide structure comprising a plurality of channels, each of the plurality of channels extending from a respective one of the plurality of inlets to a first portion of a periphery of the reaction space, each of the plurality of channels widening as the channel extends from the inlet to the reaction space; and
a substrate holder positioned to expose a supported substrate to the reaction space.

2. The reactor of claim 1, wherein the plurality of inlets are positioned on top of the reaction chamber.

3. The reactor of claim 1, wherein the plurality of inlets are positioned over a central portion of the reaction space, and wherein each of the plurality of channels extends radially outward from over the central portion to over the first portion of the periphery of the reaction space.

4. The reactor of claim 1, wherein a lower surface of the gas flow control guide structure and an upper surface of the substrate holder are configured to define the reaction space.

5. The reactor of claim 1, wherein the gas flow control guide structure comprises a plurality of gas flow control plates stacked over one another, and wherein each of the plurality of gas flow control plates defines a lower surface and sidewalls of a respective one of the plurality of channels.

6. The reactor of claim 5, wherein each of the gas flow control plates comprises a groove extending from a generally central portion of the gas flow control plate to at least a portion of an edge of the gas flow control plate, and wherein the groove widens as the groove extends from the generally central portion to the at least a portion of the edge.

7. The reactor of claim 6, wherein the plurality of gas flow control plates comprise a first gas flow control plate and a second gas flow control plate directly overlying the first gas flow control plate, wherein the first gas flow control plate comprises a groove on its upper surface, the groove extending from a central portion of the first gas flow control plate to at least a portion of an edge of the first gas flow control plate, and wherein the groove and a lower surface of the second gas flow control plate are configured to define one of the plurality of the channels.

8. The reactor of claim 5, wherein one of the plurality of gas flow control plates comprises a vertical through-hole, and wherein one of the plurality of channels is in fluid communication with one of the plurality of inlets through the vertical through-hole.

9. The reactor of claim 5, wherein the gas flow control guide further comprises a metallic plate configured to be grounded, the metallic plate being interposed between two of the plurality of the gas flow control plates.

10. The reactor of claim 5, wherein at least one of the plurality of gas flow control plates further defines a lower surface and sidewalls of an outflow channel extending from the reaction space to the exhaust outlet.

11. The reactor of claim 10, wherein a cross-sectional area of the exhaust outlet is equal to or larger than a total cross-sectional area of the plurality of inlets.

12. The reactor of claim 10, wherein a cross-sectional area of the outflow channel is equal to or larger than a total cross-sectional area of the plurality of channels.

13. The reactor of claim 10, wherein the plurality of gas flow control plates comprises an uppermost gas flow control plate, wherein the uppermost gas flow control plate defines the lower surface and sidewalls of the outflow channel, and wherein the outflow channel extends from over a second portion of the periphery of the reaction space to the exhaust outlet, the second portion of the periphery being positioned on the opposite side from the first portion of the periphery.

14. The reactor of claim 13, wherein the exhaust outlet is positioned over a central portion of the reaction space, and wherein the outflow channel extends radially inward from over the second portion of the periphery of the reaction space to over the central portion of the reaction space.

15. The reactor of claim 14, wherein the outflow channel narrows as the outflow channel extends from over the second portion of the periphery of the reaction space to over the central portion of the reaction space.

16. The reactor of claim 13, wherein the uppermost gas flow control plate comprises a groove on its upper surface, wherein the groove is configured to define the lower surface and sidewalls of the outflow channel, and wherein the groove narrows as the groove extends from over the second portion of the periphery of the reaction space to over the central portion of the reaction space.

17. The reactor of claim 13, wherein the gas flow control guide structure further comprises a purging gas channel configured to supply a purging gas directly to the second portion of the periphery of the reaction space.

18. The reactor of claim 1, wherein at least a portion of the plurality of channels extends horizontally.

19. The reactor of claim 1, wherein the plurality of channels are in fluid communication with substantially the same portion of the periphery of the reaction space.

20. The reactor of claim 1, wherein the gas flow control guide structure further comprises on a lower surface thereof an electrode configured to generate plasma in the reaction space.

21. The reactor of claim 1, wherein the exhaust outlet is positioned on top of the reaction chamber.

22. The reactor of claim 1, wherein each of the plurality of inlets is configured to be in fluid communication with an inert gas supply source.

23. An atomic layer deposition (ALD) reactor, comprising:
a reactor cover comprising a plurality of inlets and an exhaust outlet;
a reactor base comprising a substrate holder, the reactor base and the reactor cover being configured to define a reaction chamber, the reaction chamber comprising a reaction space, the reaction space comprising an upstream periphery and a downstream periphery positioned on the opposite side from the upstream periphery; and
a plurality of gas flow control plates positioned within the reactor chamber, the plurality of gas flow control plates residing over the reaction space, the plurality of gas flow control plates being stacked over one another, each of the plurality of gas flow control plates at least partially defining an inflow channel configured to guide a reactant supplied through one of the plurality of the inlets to the upstream periphery of the reaction space.

24. The ALD reactor of claim 23, wherein the plurality of gas flow control plates define a lower surface and sidewalls of an outflow channel extending from the downstream periphery of the reaction space to the exhaust outlet.

25. The ALD reactor of claim 24, wherein a cross-sectional area of the outflow channel is equal to or larger than a total cross-sectional area of the plurality of inflow channels.

26. The ALD reactor of claim 25, wherein the reactor cover comprises a reactor cover top plate which defines an upper portion of the reaction chamber, wherein the reactor cover top plate comprises an inlet side and an outlet side, the inlet side overlying the inflow channel and the outlet side overlying the outflow channel, and wherein the reactor cover top plate is thicker on the inlet side than on the outlet side.

27. The ALD reactor of claim 23, wherein the reaction space is configured to flow the reactant from the upstream periphery to the downstream periphery in a horizontal direction over the substrate holder.

28. The ALD reactor of claim 23, wherein the plurality of gas flow control plates comprise a lowermost gas flow control plate, and wherein a lower surface of the lowermost gas flow control plate and an upper surface of the substrate holder are configured to define the reaction space.

29. The ALD reactor of claim 28, wherein the lowermost gas flow control plate comprises an electrode formed on the lower surface of the lowermost gas flow control plate.

30. The ALD reactor of claim 23, wherein the plurality of gas flow control plates comprise an uppermost gas flow control plate, wherein the uppermost gas flow control plate comprises a first groove on its upper surface, and wherein the first groove and a first portion of a lower surface of the reactor cover are configured to define an inflow channel configured to guide a reactant from one of the plurality of the inlets to the upstream periphery of the reaction space.

31. The ALD reactor of claim 30, wherein the uppermost gas flow control plate comprises a second groove on its upper surface, and wherein the second groove and a second portion of the lower surface of the reactor cover are configured to define an outflow channel configured to guide excess reactant and/or a reaction by-product from the downstream periphery of the reaction space to the exhaust outlet.

32. The ALD reactor of claim 23, further comprising an outer wall configured to enclose the reactor cover and the reactor base.

33. The ALD reactor of claim 23, further comprising a gas manifold over the reactor cover, the gas manifold comprising a plurality of openings in fluid communication with the plurality of inlets and the exhaust outlet.

34. The ALD reactor of claim 23, wherein the reactor base is detachable from the reactor cover.

35. The ALD reactor of claim 23, further comprising a reactor base driver configured to provide the reactor base with a vertical movement.

36. The ALD reactor of claim 23, further comprising a first inert gas supply passage formed between the reactor cover and the reactor base, the first inert gas supply passage being configured to supply an inert gas to the upstream periphery of the reaction space.

37. The ALD reactor of claim 23, further comprising a second inert gas supply passage formed between the reactor cover and the reactor base, the second inert gas supply passage being configured to supply an inert gas to the downstream periphery of the reaction space.

38. A method of depositing a reactant on a substrate in a reaction space, the reaction space comprising an upstream periphery and a downstream periphery, the method comprising a plurality of atomic layer deposition cycles, each comprising:
supplying a first reactant to the reaction space, wherein supplying the first reactant comprises in sequence: flowing the first reactant outwardly and horizontally at a first vertical level toward the upstream periphery of the reaction space while widening a first flow path of the first reactant, and flowing the first reactant vertically to the upstream periphery and into the reaction space;
reacting the first reactant with a surface of the substrate;
removing excess first reactant from the reaction space;
supplying a second reactant to the reaction space, wherein supplying the second reactant comprises in sequence: flowing the second reactant horizontally at a second vertical level toward the upstream periphery of the reaction space while widening a second flow path of the second reactant, and flowing the second reactant vertically from the second vertical level to the upstream periphery and into the reaction space;
reacting the second reactant with the surface of the substrate; and
removing excess second reactant from the reaction space.

39. The method of claim 38, wherein supplying the first reactant to the reaction space further comprises supplying an inert gas to the second flow path.

40. The method of claim 38, wherein supplying the second reactant to the reaction space further comprises supplying an inert gas to the first flow path.

41. The method of claim 38, further comprising repeating the cycle sequentially at least 5 times.

42. The method of claim 38, further comprising supplying, reacting, and removing a third reactant in at least one cycle.

43. The method of claim 38, wherein reacting the reactant comprises generating plasma in the reaction space.

44. The method of claim 38, wherein the reaction space is lower than the first and second vertical levels.

45. The method of claim 38, wherein removing excess first reactant comprises:
flowing an inert gas to both the first and second flow paths;
flowing the excess first reactant from the downstream periphery of the reaction space vertically away from the reaction space;
flowing the excess first reactant horizontally while narrowing a third flow path of the excess reactant; and
exhausting the excess first reactant from the third flow path.

46. The method of claim 38, wherein removing excess first reactant comprises in sequence:
flowing an inert gas to both the first and second flow paths;
flowing the excess first reactant from the downstream periphery of the reaction space vertically away from the reaction space;
flowing the excess first reactant horizontally while narrowing a third flow path of the excess reactant; and
exhausting the excess first reactant from the third flow path.

47. The method of claim 46, wherein removing excess second reactant comprises in sequence:
flowing the excess second reactant from the downstream periphery of the reaction space vertically away from the reaction space;
flowing the excess second reactant horizontally along the narrowing third flow path; and
exhausting the excess first reactant from the third flow path.

48. A method of assembling an atomic layer deposition (ALD) reactor, comprising:
providing a reactor cover comprising a top plate and a sidewall, the top plate comprising a plurality of inlets, the top plate defining an upper surface of a reaction chamber, the sidewall defining a side surface of the reaction chamber, the reaction chamber comprising a reaction space;
placing a gas flow control guide structure into the reaction chamber so that at least a portion of the gas flow control guide structure is in contact with the upper surface of the reaction chamber, the gas flow control guide structure comprising a plurality of inflow channels, each of the plurality of inflow channels extending from a respective one of the plurality of inlets to a first portion of a periphery of the reaction space; and
providing a reactor base to be in sealing contact with the sidewall of the reactor cover so that an upper surface of the reactor base and a lower surface of the gas flow control guide structure define the reaction space.

49. The method of claim 48, wherein the gas flow control guide structure comprises at least two gas flow control plates stacked over one another, and wherein the at least two gas flow control plates are configured to at least partially define at least two inflow channels, respectively.

50. The method of claim 48, wherein an uppermost plate of the at least two gas flow control plates is configured to at least partially define an outflow channel.
